(19) United States
(12) Patent Application Publication
(10) Pub. No.: US 2025/0285886 A1
(43) Pub. Date: Sep. 11, 2025

(54) METHOD OF TREATING THIN FILMS AND METHOD OF MANUFACTURING MEMORY DEVICE

(71) Applicant: EGTM Co., Ltd., Suwon-si (KR)

(72) Inventors: Kyu Ho CHO, Suwon-si (KR); Hyun Ju JUNG, Suwon-si (KR); Ha Na KIM, Suwon-si (KR); Ju Hwan JEONG, Suwon-si (KR); Hyeon Sik CHO, Suwon-si (KR); Sung Jun JI, Suwon-si (KR); Kun Hee KIM, Suwon-si (KR); Jae Min KIM, Suwon-si (KR)

(73) Assignee: EGTM Co., Ltd., Suwon-si (KR)

(21) Appl. No.: 19/075,689

(22) Filed: Mar. 10, 2025

(30) Foreign Application Priority Data
Mar. 11, 2024 (KR) 10-2024-0033987
Nov. 8, 2024 (KR) 10-2024-0158568

(51) Int. Cl. H01L 21/67

(52) U.S. Cl. CPC H01L 21/67069

(57) ABSTRACT

Disclosed is a method of treating thin films, the method comprising: supplying a precursor to the inside of a chamber where a substrate is placed to adsorb the precursor onto the substrate; purging the inside of the chamber; supplying an etching initiator to the inside of the chamber; purging the inside of the chamber; supplying a reactant to the inside of the chamber; and purging the inside of the chamber.

### TECHNICAL FIELD

The present invention relates to a method of treating thin films and a method of manufacturing a memory device including the same, and more particularly, to a method of treating thin films using the selective adsorption characteristics of a precursor, and a method of manufacturing a memory device including the same.

### BACKGROUND

The primary mechanism of conventional top-down patterning has been to deposit a desired material in the form of a thin film and then fabricate it into a desired size and shape through isotropic wet etching, anisotropic dry etching, reactive ion etching (RIE), or the like. However, with the demand for continuous high performance/low power consumption, along with increasingly miniaturized pattern sizes and the requirement for innovation beyond the current three-dimensional structure to multi-dimensional stacked structures, etching technology with high precision at the atomic level, beyond existing wet/dry etching techniques, has been required.

Hydrogen fluoride used in conventional atomic layer etching methods has excellent etching performance due to its strong reactivity, but it has the problem that it is difficult to etch a very thin thickness due to its fast reaction rate. In addition, in the process of removing fluorine atoms from the surface, it can penetrate into undesired areas and cause characteristic degradation of the device.

Therefore, there is a need to develop materials and processes that can uniformly etch thin films using materials that have lower reactivity than hydrogen fluoride and do not cause contamination. However, in the case of materials having lower reactivity than hydrogen fluoride, there is a difficulty in accurately controlling the degree of etching because the etching rate is low.

An object of the present invention is to provide a method of treating thin films that can control the degree of etching and a method of manufacturing a memory device including the same.

Other objects of the present invention will become more apparent from the following detailed description.

### SUMMARY

Disclosed is a method of treating thin films, the method comprising: supplying a precursor to the inside of a chamber where a substrate is placed to adsorb the precursor onto the substrate; purging the inside of the chamber; supplying an etching initiator to the inside of the chamber; purging the inside of the chamber; supplying a reactant to the inside of the chamber; and purging the inside of the chamber.

The etching initiator may be represented by the following <Chemical Formula 1>:

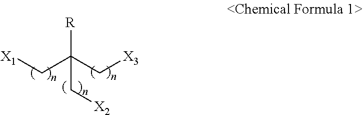

in <Chemical Formula 1>, n is each independently selected from integers of 0 to 5,
X1 to X3 are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

The etching initiator may be any one of Trimethyl orthoformate (TMOF), Triethyl orthoformate (TEOF), Dimethylformamide dimethyl acetal (DFDA), and Tris(dimethylamino)methane (TDMAM).

The etching initiator may be represented by the following <Chemical Formula 2> or <Chemical Formula 3>:

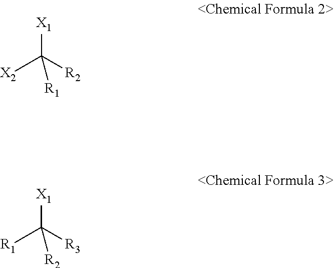

in <Chemical Formula 2> or <Chemical Formula 3>, X1 to X2 are independently hydrogen, chlorine element, and a chloroalkyl group having 1 to 5 carbon atoms,
R1 to R3 are independently selected from hydrogen, linear, branched, or cyclic alkyl groups having 1 to 5 carbon atoms, aryl groups having 6 to 12 carbon atoms, hydroxy groups having 0 to 4 carbon atoms, or alkoxy groups having 0 to 4 carbon atoms, and a dialkylamino group having 0 to 4 carbon atoms.

The reactant may be any one of O₃, O₂, or H₂O, NH₃, and H₂.

The thin film may have one of Al, Nb, Hf, Ti, Si, Ta, Mo, Zr, and W as a central element.

The thin film may be any one of a metal film, a metal oxide, a metal nitride, a metal sulfide, a silicon nitride, and a silicon oxide.

The thin film may be a binary compound or a ternary compound doped with one or more elements.

The thin film treatment method may be performed at 50 to 700° C.

The method further comprising, between supplying the precursor and supplying the etching initiator: supplying a promoting material to the inside of the chamber; and purging the inside of the chamber, wherein the promoting material is O₂.

Disclosed is a method of manufacturing a volatile memory device may include the aforementioned method of treating thin films.

Disclosed is a method of manufacturing a non-volatile memory device may include the aforementioned method of treating thin films.

### BRIEF DESCRIPTION OF THE DRAWINGS

FIG. 1 is a flowchart illustrating a method of treating thin films according to Example 1 of the present invention.

FIG. 2 is a graph schematically showing a supply cycle according to Example 1 of the present invention.

FIG. 3 is a graph showing the Nb content by XPS analysis according to Comparative Example 1.

FIG. 4 is a graph showing the Nb content by XPS analysis according to Example 1.

FIG. 5 is a graph comparing the Nb content by XPS analysis according to Comparative Example 1 and Example 2.

FIG. 6 is a graph comparing the Ta content by XPS analysis according to Comparative Examples 2 and 3 and Example 3.

### DETAILED DESCRIPTION

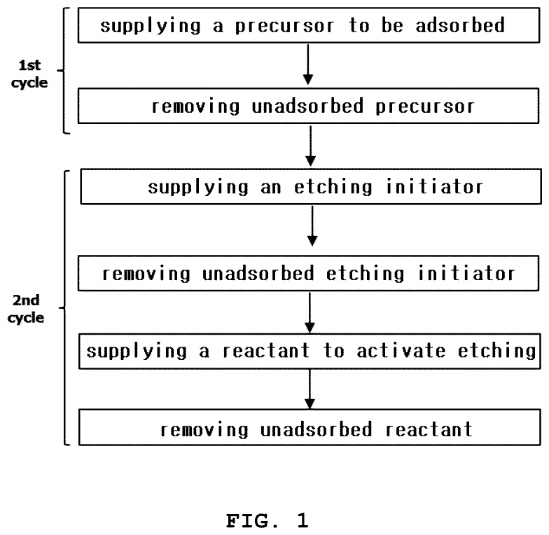

Hereinafter, embodiments of the present invention will be described with reference to FIGS 1 to 6. The embodiments of the present invention can be modified in various forms, and the scope of the present invention should not be interpreted as being limited to the embodiments described below.

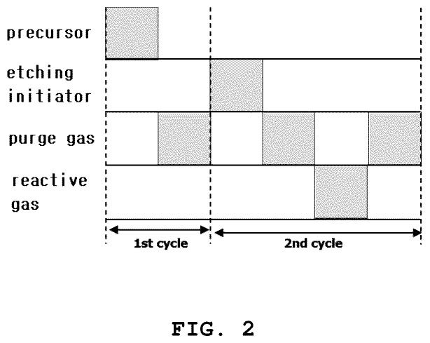

FIG. 1 is a flowchart illustrating a method of treating thin films according to Example 1 of the present invention, and FIG. 2 is a graph schematically showing a supply cycle according to Example 1 of the present invention. A substrate is loaded into a process chamber, and following process conditions can be adjusted. The process conditions may include a temperature of the substrate or process chamber, a pressure in the process chamber, gas flow rate, and the temperature is 50 to 700° C.

The substrate is exposed to a precursor supplied to the inside of the chamber, and the precursor is adsorbed on the thin film formed on the surface of the substrate. The precursor is supplied at 50 to 700° C.

Thereafter, a purge gas (for example, an inert gas such as Ar) is supplied to the inside of the chamber to discharge the unadsorbed precursor or by-products.

The above process corresponds to the first cycle (1st cycle) shown in FIGS. 1 and 2, and the following process corresponds to the second cycle (2nd cycle) shown in FIGS. 1 and 2. The thin film is treated through the following process.

The substrate is exposed to an etching initiator supplied to the inside of the chamber. The etching initiator is supplied at 50 to 700° C.

Specifically, the etching initiator may be represented by the following <Chemical Formula 1>.

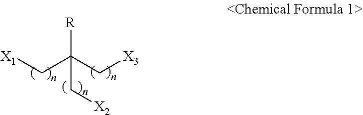

in <Chemical Formula 1>, n is each independently selected from integers of 0 to 5,
X1 to X3 are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

Specifically, the etching initiator may be any one of Trimethyl orthoformate (TMOF), Triethyl orthoformate (TEOF), Dimethylformamide dimethyl acetal (DFDA), and Tris(dimethylamino)methane (TDMAM).

Also, the etching initiator may be represented by the following <Chemical Formula 2> or <Chemical Formula 3>:

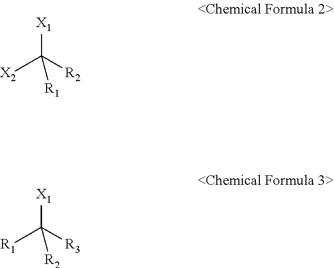

in <Chemical Formula 2> or <Chemical Formula 3>, X1 to X2 are independently hydrogen, chlorine element, and a chloroalkyl group having 1 to 5 carbon atoms,
R1 to R3 are independently selected from hydrogen, linear, branched, or cyclic alkyl groups having 1 to 5 carbon atoms, aryl groups having 6 to 12 carbon atoms, hydroxy groups having 0 to 4 carbon atoms, or alkoxy groups having 0 to 4 carbon atoms, and a dialkylamino group having 0 to 4 carbon atoms.

Thereafter, a purge gas (for example, an inert gas such as Ar) is supplied to the inside of the chamber to discharge the unadsorbed etching initiator or by-products.

Thereafter, the substrate is exposed to a reactant (or reactive gas) supplied to the inside of the chamber, and etching is activated by the reactant and reacts with the precursor to form a thin film. The reactant may be any one of O₃, O₂, or H₂O, NH₃, and H₂. The thin film may have one of Al, Nb, Hf, Ti, Si, Ta, Mo, Zr, and W as a central element. The thin film may be any one of a metal film, a metal oxide, a metal nitride, a metal sulfide, a silicon nitride, and a silicon oxide. In addition, the thin film may be a binary compound or a ternary compound doped with one or more elements.

Thereafter, a purge gas (for example, an inert gas such as Ar) is supplied to the inside of the chamber to discharge the unreacted materials or by-products.

### Comparative Example 1—Nb Precursor+O₃ (Dep)→Trimethyl Orthoformate+O₃ (Etch)

In a first cycle, a niobium oxide film was formed on a SiCN substrate and a TiN substrate. The niobium oxide film was formed through an ALD process, the process temperature was 340° C., and O₃ gas was used as a reactant.

In a second cycle, Trimethyl Orthoformate was supplied to the above substrate as an etching initiator. The process temperature was 340° C., and O₃ gas) was used as a reactant.

The niobium precursor and etching initiator supply process is as follows, and the following processes 1)-4) were performed as a first cycle, and processes 5)-8) were performed as a second cycle.
1) Using Ar as a carrier gas, the niobium precursor EtMeCp-Nb=NtBu(Cl)₂ is supplied to the reaction chamber, and the niobium precursor is adsorbed on the SiCN substrate/TiN substrate.
2) Ar gas is supplied into the reaction chamber to remove unadsorbed niobium precursor or byproducts.
3) O₃ gas is supplied to the reaction chamber to form a niobium oxide film.
4) Ar gas is supplied into the reaction chamber to remove unreacted materials or byproducts.
5) Using Ar as a carrier gas, the etching initiator Trimethyl Orthoformate is supplied to the reaction chamber and adsorbed on the SiCN substrate/TiN substrate.
6) Ar gas is supplied into the reaction chamber to remove unadsorbed etching initiator or byproducts.
7) O₃ gas) is supplied to the reaction chamber to activate etching.
8) Ar gas is supplied into the reaction chamber to remove unreacted materials or byproducts.

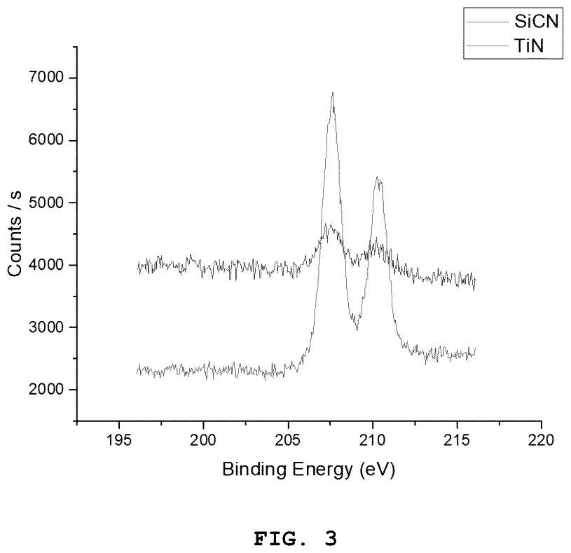

When the first cycle was repeated 5 times and the second cycle was repeated 50 times, the niobium content was confirmed to be 0.22% (SiCN substrate) and 1.20% (TiN substrate), and the selectivity was confirmed to be 1:5.5 (see [Table 1] and FIG. 3 below).

TABLE 1

| | | | | | | XPS Nb % | | |
|---|---|---|---|---|---|---|---|---|
| | Temp. | | Etching | Reac- | | On | On | Selec- |
| Item | (° C.) | Precursor | Initiator | tant | Process | SiCN | TiN | tivity |
| | 340 | EtMeCp − | | O₃ | Precursor→ | 0.64 | 1.76 | 1:2.8 |
| | | Nb═NtBu(Cl)₂ | | | Reactant | | | |
| Compar- | 340 | — | Trimethyl | O₃ | Etching | 0.22 | 1.20 | 1:5.5 |
| ative | | | Orthoformate | | initiator→ | | | |
| Example 1 | | | | | Reactant | | | |

### Example 1—Nb Precursor (Dep)→Trimethyl Orthoformate+O₃ (Etch)

In a first cycle, a niobium precursor was adsorbed on the SiCN substrate and the TiN substrate. The niobium precursor was adsorbed through an ALA (Atomic Layer Adsorption) process, the process temperature was 340° C., and no reactant was used.

In a second cycle, Trimethyl Orthoformate was supplied to the above substrate as an etching initiator. The process temperature was 340° C., and O₃ gas was used as a reactant.

The niobium precursor and etching initiator supply process is as follows, and the following processes 1)-2) were performed as a first cycle, and processes 3)-6) were performed as a second cycle (see FIGS. 1 and 2).
1) Using Ar as a carrier gas, the niobium precursor EtMeCp-Nb=NtBu(Cl)₂ is supplied to the reaction chamber, and the niobium precursor is adsorbed on the SiCN substrate/TiN substrate.
2) Ar gas is supplied into the reaction chamber to remove unadsorbed niobium precursor or byproducts.
3) Using Ar as a carrier gas, the etching initiator Trimethyl Orthoformate is supplied to the reaction chamber and adsorbed on the SiCN substrate/TiN substrate.
4) Ar gas is supplied into the reaction chamber to remove unadsorbed etching initiator or byproducts.
5) O₃ gas) is supplied to the reaction chamber to activate etching.
6) Ar gas is supplied into the reaction chamber to remove unreacted materials or byproducts.

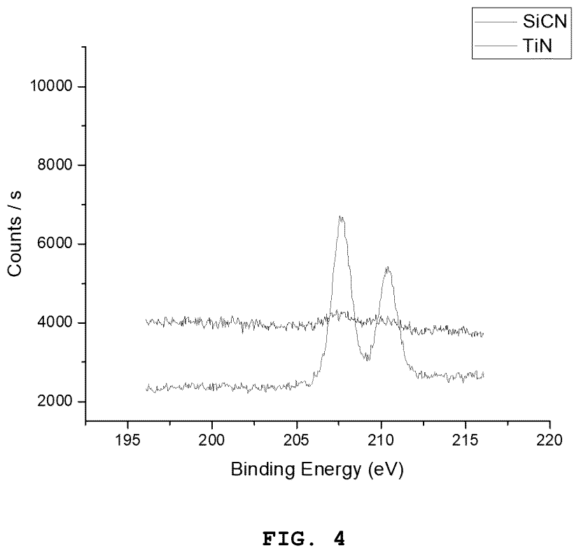

When the first cycle was repeated 100 times and the second cycle was repeated 50 times, the niobium content was confirmed to be 0.13% (SiCN substrate) and 1.21% (TiN substrate), and it was confirmed that the niobium in the SiCN substrate, which is a non-growth area, was reduced by about 50%, improving the selectivity to 1:9.3 (see [Table 2] and FIG. 4 below).

TABLE 2

| | | | | | | XPS Nb % | | |
|---|---|---|---|---|---|---|---|---|
| | Temp. | | Etching | Reac- | | On | On | Selec- |
| Item | (° C.) | Precursor | Initiator | tant | Process | SiCN | TiN | tivity |
| | 340 | EtMeCp − | | X | Precursor | 0.32 | 1.60 | 1:5 |
| | | Nb═NtBu(Cl)₂ | | | | | | |
| Exam- | 340 | — | Trimethyl | O₃ | Etching | 0.13 | 1.21 | 1:9.3 |
| ple 1 | | | Orthoformate | | initiator→ | | | |
| | | | | | Reactant | | | |

FIG. 3 is a graph showing the Nb content by XPS analysis according to Comparative Example 1, FIG. 4 is a graph showing the Nb content by XPS analysis according to Example 1.

As described above, based on the TiN substrate corresponding to the growth area, it is confirmed that the niobium in the SiCN substrate corresponding to the non-growth area is significantly reduced (0.22% (Comparative Example 1)→0.13% (Example)), improving the selectivity (1:5.5 (Comparative Example 1)→1:9.3 (Example)). For example, the growth area may include a metal thin film such as a titanium nitride film or a niobium nitride film, and the non-growth area may include a non-metal thin film such as a silicon nitride film.

### Example 2—Nb Precursor (Dep)→Trimethyl Orthoformate+O₃ (Etch)

In a first cycle, the niobium precursor was adsorbed on the SiO₂ substrate and the TiN substrate. The niobium precursor was adsorbed through an ALA (Atomic Layer Adsorption) process, the process temperature was 340° C., and no reactant was used.

In a second cycle, Trimethyl Orthoformate was supplied to the above substrate as an etching initiator. The process temperature was 340° C., and O₃ gas was used as a reactant.

The niobium precursor and etching initiator supply process is as follows, and the following processes 1)-2) were performed as a first cycle, and processes 3)-6) were performed as a second cycle (see FIGS. 1 and 2).
1) Using Ar as a carrier gas, the niobium precursor EtMeCp-Nb=NtBu(Cl)₂ is supplied to the reaction chamber, and the niobium precursor is adsorbed on the SiO₂ substrate/TiN substrate.
2) Ar gas is supplied into the reaction chamber to remove unadsorbed niobium precursor or byproducts.
3) Using Ar as a carrier gas, the etching initiator Trimethyl Orthoformate is supplied to the reaction chamber and adsorbed on the SiO₂ substrate/TiN substrate.
4) Ar gas is supplied into the reaction chamber to remove unadsorbed etching initiator or byproducts.
5) O₃ gas) is supplied to the reaction chamber to activate etching.
6) Ar gas is supplied into the reaction chamber to remove unreacted materials or byproducts.

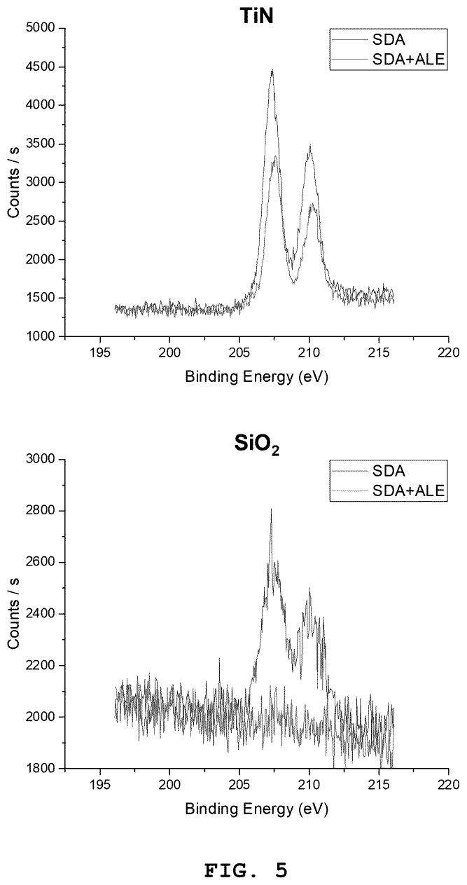

When the first cycle was repeated 100 times and the second cycle was repeated 50 times, the niobium content was confirmed to be 0% (SiO₂ substrate) and 1.00% (TiN substrate), and it was confirmed that the selectivity was improved (see [Table 3] and FIG. 5 below).

TABLE 3

| | | | | | | XPS Nb % | | |
|---|---|---|---|---|---|---|---|---|
| | Temp. | | Etching | Reac- | | On | On | Selec- |
| Item | (° C.) | Precursor | Initiator | tant | Process | SiO₂ | TiN | tivity |
| | 340 | EtMeCp − | | X | Precursor | 0.29 | 1.52 | 0.68 |
| | | Nb=NtBu(Cl)₂ | | | | | | |
| Exam- | 340 | — | Trimethyl | O₃ | Etching | 0.00 | 1.00 | 1 |
| ple 2 | | | Orthoformate | | initiator→ | | | |
| | | | | | Reactant | | | |

FIG. 5 is a graph comparing the Nb content by XPS analysis according to Comparative Example 1 and Example 2. Since TiN with a large surface energy forms a relatively strong bond through decomposition adsorption, the etching effect is insignificant. In SiO₂ with a low surface energy, a weak bond is formed, so the etching effect is greatly improved.

### Comparative Example 2—Ta Precursor+O₃ (Dep)

A tantalum oxide film was formed on a SiCN substrate and a TiN substrate. The tantalum oxide film was formed through an ALD process, the process temperature was 300° C., and O₃ gas was used as a reactant.

The tantalum precursor supply process is as follows.
1) Using Ar as a carrier gas, the tantalum precursor EtMeCp-Ta=NtBu(Cl)₂ is supplied to the reaction chamber, and the tantalum precursor is adsorbed on the SiCN substrate/TiN substrate.
2) Ar gas is supplied into the reaction chamber to remove unadsorbed tantalum precursor or byproducts.
3) O₃ gas) is supplied to the reaction chamber to form a tantalum oxide film.
4) Ar gas is supplied into the reaction chamber to remove unreacted materials or byproducts.

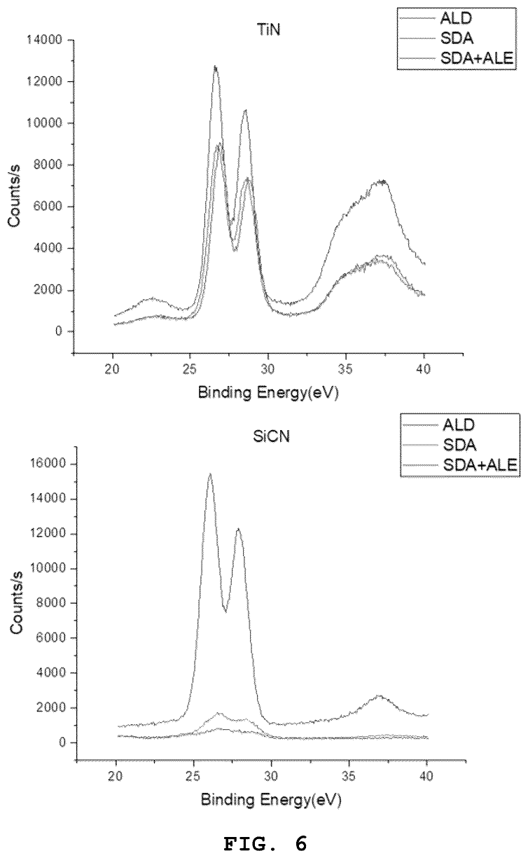

In the case of the above cycle, the tantalum content was confirmed to be 3.16% (SiCN substrate) and 2.89% (TiN substrate), and the selectivity was confirmed to be 1:0.9 (see [Table 4] and FIG. 6 below).

### Comparative Example 3—Ta Precursor+O₂ (Dep)

A tantalum oxide film was formed on a SiCN substrate and a TiN substrate. The tantalum oxide film was formed through an ALD process, the process temperature was 300° C., and O₂ gas was used as a promoting material.

The tantalum precursor supply process is as follows.
1) Using Ar as a carrier gas, the tantalum precursor EtMeCp-Ta=NtBu(Cl)₂ is supplied to the reaction chamber, and the tantalum precursor is adsorbed on the SiCN substrate/TiN substrate.
2) Ar gas is supplied into the reaction chamber to remove unadsorbed tantalum precursor or byproducts.
3) O₂ gas is supplied to the reaction chamber to promote selective decomposition/adsorption.
4) Ar gas is supplied into the reaction chamber to remove unreacted materials or byproducts.

In the case of the above cycle, the tantalum content was confirmed to be 0.75% (SiCN substrate) and 5.16% (TiN substrate), and the selectivity was confirmed to be 1:6.9 (see [Table 4] and FIG. 6 below).

### Example 3—Ta Precursor+O₂ (Dep)→Dimethylformamide dimethyl acetal+O₃ (Etch)

In a first cycle, a tantalum oxide film was formed on a SiCN substrate and a TiN substrate. A tantalum oxide film was formed through an ALD process, the process temperature was 300° C., and O₂ gas was used as a promoting material.

In a second cycle, Dimethylformamide dimethyl acetal was supplied to the above substrate as an etching initiator. The process temperature was 300° C., and O₃ gas was used as a reactant.

The tantalum precursor and etching initiator supply process is as follows, and the following processes 1)-2) were performed as a first cycle, and processes 3)-6) were performed as a second cycle (see FIGS. 1 and 2).
1) Using Ar as a carrier gas, the tantalum precursor EtMeCp-Ta=NtBu(Cl)₂ is supplied to the reaction chamber, and the tantalum precursor is adsorbed on the SiCN substrate/TiN substrate.
2) Ar gas is supplied into the reaction chamber to remove unadsorbed tantalum precursor or byproducts.
3) O₂ gas is supplied to the reaction chamber to promote selective decomposition/adsorption.
4) Ar gas is supplied to the reaction chamber to remove unreacted materials or byproducts.
5) Using Ar as a carrier gas, the etching initiator Dimethylformamide dimethyl acetal is supplied to the reaction chamber and adsorbed on the SiCN substrate/TiN substrate.
6) Ar gas is supplied into the reaction chamber to remove unadsorbed etching initiator or byproducts.
7) O₃ gas is supplied to the reaction chamber to activate etching.
8) Ar gas is supplied into the reaction chamber to remove unreacted materials or byproducts.

When the first cycle was repeated 100 times and the second cycle was repeated 10 times, the tantalum content was confirmed to be 0.35% (SiCN substrate) and 4.93% (TiN substrate), and it was confirmed that the tantalum in the SiCN substrate, which is a non-growth area, was reduced by about 90%, improving the selectivity to 1:14.1 (see [Table 4] and FIG. 6 below). FIG. 6 is a graph comparing the Ta content by XPS analysis according to Comparative Examples 2 and 3 and Example 3.

TABLE 4

| | | | Reactant/ | | | XPS Ta % | | |
|---|---|---|---|---|---|---|---|---|
| | Temp. | | Promoting | Etching | Etching | On | On | Selec- |
| Item | (° C.) | Precursor | material | Initiator | Activator | SiCN | TiN | tivity |
| Compar- | 300 | EtMeCp − | O₃ | — | — | 3.16 | 2.89 | 1:0.9 |
| ative | | Ta=NtBu(Cl)₂ | | | | | | |
| Exam- | | | | | | | | |
| ple 2 | | | | | | | | |
| Compar- | 300 | EtMeCp − | O₂ | — | — | 0.75 | 5.16 | 1:6.9 |
| ative | | Ta=NtBu(Cl)₂ | | | | | | |
| Exam- | | | | | | | | |
| ple 3 | | | | | | | | |
| Exam- | 300 | EtMeCp − | O₂ | Dimethyl- | O₃ | 0.35 | 4.93 | 1:14.1 |
| ple 3 | | Ta=NtBu(Cl)₂ | | formamide | | | | |
| | | | | dimethyl | | | | |
| | | | | acetal | | | | |

According to embodiments of the present invention, by applying a selective adsorption process using the reactivity difference between the surface of the substrate and the precursor to the pre-etching step, the degree of etching can be controlled using the characteristic that the degree of decomposition of the precursor varies depending on the surface energy in the selective adsorption process.

When the surface energy is high, the precursor is decomposed to form a strong bond with the surface through decomposition adsorption, but when the surface energy is low, the precursor forms a weak bond in a chemisorbed state on the surface, so subsequent etching is easy. At this time, if a reactant is supplied, a reaction product can be formed regardless of whether the precursor is decomposed, but in this embodiment, since the reactant is not supplied, the etching of the weakly bonded surface by the etching material supplied later can be promoted.

The present invention has been explained in detail with reference to embodiments, but other embodiments may be included. Accordingly, the technical idea and scope described in the claims below are not limited to the embodiments.

1. A method of treating thin films, the method comprising:
supplying a precursor to the inside of a chamber where a substrate is placed to adsorb the precursor onto the substrate;
purging the inside of the chamber;
supplying an etching initiator to the inside of the chamber;
purging the inside of the chamber;
supplying a reactant to the inside of the chamber; and
purging the inside of the chamber.

2. The method of claim 1, wherein the etching initiator is represented by the following <Chemical Formula 1>: 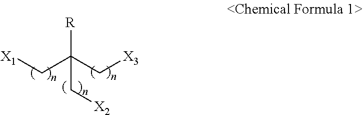
in <Chemical Formula 1>, n is each independently selected from integers of 0 to 5,
X1 to X3 are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

3. The method of claim 1, wherein the etching initiator is any one of Trimethyl orthoformate (TMOF), Triethyl orthoformate (TEOF), Dimethylformamide dimethyl acetal (DFDA), and Tris(dimethylamino)methane (TDMAM).

4. The method of claim 1, wherein the etching initiator is represented by the following <Chemical Formula 2> or <Chemical Formula 3>: 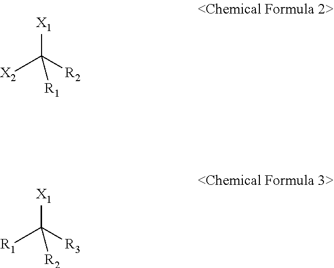
in <Chemical Formula 2> or <Chemical Formula 3>, X1 to X2 are independently hydrogen, chlorine element, and a chloroalkyl group having 1 to 5 carbon atoms,
R1 to R3 are independently selected from hydrogen, linear, branched, or cyclic alkyl groups having 1 to 5 carbon atoms, aryl groups having 6 to 12 carbon atoms, hydroxy groups having 0 to 4 carbon atoms, or alkoxy groups having 0 to 4 carbon atoms, and a dialkylamino group having 0 to 4 carbon atoms.

5. The method of claim 1, wherein the reactant is any one of O₃, O₂, or H₂O, NH₃, and H₂.

6. The method of claim 1, wherein the thin film has one of Al, Nb, Hf, Ti, Si, Ta, Mo, Zr, and W as a central element.

7. The method of claim 1, wherein the thin film is any one of a metal film, a metal oxide, a metal nitride, a metal sulfide, a silicon nitride, and a silicon oxide.

8. The method of claim 1, wherein the thin film is a binary compound or a ternary compound doped with one or more elements.

9. The method of claim 1, wherein the thin film treatment method is performed at 50 to 700° C.

10. The method of claim 1, wherein the method further comprising, between supplying the precursor and supplying the etching initiator:
supplying a promoting material to the inside of the chamber; and
purging the inside of the chamber,
wherein the promoting material is O₂.

11. A method of manufacturing a volatile memory device, the method comprising the method of treating thin films according to claim 1.

12. A method of manufacturing a non-volatile memory device, the method comprising the method of treating thin films according to claim 1.

13. A method of manufacturing a volatile memory device, the method comprising the method of treating thin films according to claim 2.

14. A method of manufacturing a volatile memory device, the method comprising the method of treating thin films according to claim 3.

15. A method of manufacturing a volatile memory device, the method comprising the method of treating thin films according to claim 4.

16. A method of manufacturing a volatile memory device, the method comprising the method of treating thin films according to claim 5.

17. A method of manufacturing a non-volatile memory device, the method comprising the method of treating thin films according to claim 2.

18. A method of manufacturing a non-volatile memory device, the method comprising the method of treating thin films according to claim 3.

19. A method of manufacturing a non-volatile memory device, the method comprising the method of treating thin films according to claim 4.

20. A method of manufacturing a non-volatile memory device, the method comprising the method of treating thin films according to claim 5.
